(19) United States
(12) Patent Application Publication
(10) Pub. No.: US 2023/0407153 A1
(43) Pub. Date: Dec. 21, 2023

(54) DE-BONDABLE POLYURETHANE ADHESIVES BASED ON THERMALLY EXPANDABLE MICROSPHERES

(71) Applicant: BASF SE, Ludwigshafen am Rhein (DE)

(72) Inventors: Yuan Yan GU, Shanghai (CN); Hong Tao SHAO, Shanghai (CN); Hui GE, Shanghai (CN); Li Ping WANG, Shanghai (CN)

(21) Appl. No.: 18/247,082

(22) PCT Filed: Sep. 7, 2021
(86) PCT No.: PCT/EP2021/074578

§ 371 Date: Mar. 29, 2023

(30) Foreign Application Priority Data
Sep. 30, 2020 (WO) PCT/CN2020/119412

(51) Int. Cl. C09J 175/08; C09J 11/08; C09J 5/06; H01L 21/683

(52) U.S. Cl. CPC C09J 175/08; C09J 11/08; C09J 5/06; H01L 21/6836; C09J 2475/00

(57) ABSTRACT

Disclosed herein are de-bondable polyurethane adhesives based on thermally expandable microspheres, obtainable or obtained by the reaction of the components of (A) at least one di- or polyisocyanate, (B) at least one polyol, (C) catalyst, (D) thermally expandable microspheres, and (E) other additives, wherein the isocyanate index of the reaction is set in the range of from 28 to 65. Additionally disclosed herein is a method of using the de-bondable polyurethane adhesives for de-bonding metal and cutting pad during wafer cutting. Further disclosed herein is a method of using the de-bondable polyurethane adhesives in mechanical property testing sample preparation.

### TECHNICAL FIELD

The invention relates to de-bondable polyurethane adhesives based on thermally expandable microspheres, obtainable or obtained by the reaction of the components of (A) at least one di- or polyisocyanate, (B) at least one polyol, (C) catalyst, (D) thermally expandable microspheres, and (E) other additives, wherein the isocyanate index of the reaction is set in the range of from 28 to 65. The present invention also relates to the use of said de-bondable polyurethane adhesives for de-bonding metal and cutting pad during wafer cutting. Moreover, the present invention relates to the use of said de-bondable polyurethane adhesives in mechanical property testing sample preparation.

### BACKGROUND

De-bondable adhesive is a type of adhesive that can provide necessary adhesion between various surfaces when needed, but will go through adhesive failure under certain external conditions, such as heat, light, UV, etc. A de-bondable adhesive that can release efficiently from its bonded surface can have wide use in various areas, such as consumer electronics, home repairs, etc. To facilitate the de-bonding of the adhesive from bonded surface, expandable microspheres have been incorporated into the formula of the adhesive. Such an adhesive can have significant thermal expansion when the materials are heated above the “starting temperature” of the microspheres, thus leading to a fast and clean de-bonding from bonded surfaces.

Expandable microspheres are a class of particles with core-shell structure, wherein the particle shell is composed of cross-linked polymer and the core is composed of physical blowing agent (e.g. paraffins with low boiling points). By adjusting the wall thickness, T_{g}, and the composition of the wall, as well as the composition of blowing agent, i.e. the low boiling point chemicals, the microspheres can be designed to have a wide range of expansion starting temperature and expansion rate. Such a material has recently been explored as a special blowing agent for PU foam systems, but its application in a PU adhesive is a relatively under-explored area.

Wafer cutting using multiwire diamond saw is a critical process in the manufacturing of monocrystal and polycrystal silicon wafers that can be used in photovoltaic industry and microelectronic chips. This technology has seen significant increase in the market in recent years and is still rapidly growing to become the mainstream cutting technology in the wafer industry. In this manufacturing process, two types of de-bondable adhesives are needed: 1) between the Si ingot and a disposable cutting pad, and 2) the disposable cutting pad and the metal plate on the cutting equipment. Both adhesives need to be de-bonded under different conditions to allow clean release of the sliced wafer and recovery of the metal plates. The adhesive technology described herein can go through significant de-bonding in hot water (close to boiling point) while stay stable in 70° C., which is a very challenging task to achieve.

CN104031597B discloses a PU-acrylate anaerobic adhesive that can release in hot water. The adhesive is claimed to be able to release under 60-75° C. automatically. Such release, as assumed, is due to the glass transition of the adhesive, which allows it to soften in hot water. This temperature is relatively low and cannot distinguish a clear 2-step de-bonding process needed in the wafer cutting. Besides, no expandable microspheres have been added into the adhesives.

U.S. Pat. No. 9,714,317B2 discloses epoxy adhesive as a temporary adhesive to provide bonding to the Si ingot which can release in water of 55-80° C. Epoxy solutions are significantly more rigid, having a high Shore D hardness. This solution has a potential weakness that the wafer damage rate could be high due to the higher product hardness and brittleness, which causes edge damage in the wafers. Epoxy solution described herein contains water soluble polymer, which poses a potential failure risk during diamond wire cutting process, as the adhesive would constantly be exposed to water spray and thereby get weaken due to water solvation in the adhesive. Another shortcoming is the higher thiol odor of the adhesive. This is a concern for work safety of the operators. Again, no expandable microspheres have been added into the adhesives thereof.

CN1192070C discloses a composition comprising an adhesive agent, such as PU, with thermo-expandable microcapsules which act as pressure actuators dispersed therein. The capsules are heat triggered so as to release at least one expandable volatile agent encapsulated within the microcapsule shell. Nevertheless, this patent includes no examples, and thus no experimental data to prove the effects claimed therein. No details about the preparation of the PU adhesives have been mentioned throughout the context of this patent. Moreover, since this composition is used as a glazing adhesive, the thermo-expandable microcapsules expand upon heat in atmosphere, rather than in hot water, and thus the starting temperature of the microcapsules can be as high as 150° C.

It is still needed in the art to provide adhesives for the de-bonding of bonded surfaces, which provide necessary adhesion under various conditions, and can release efficiently and cleanly upon heating in certain medium, such as hot water. Particularly, the adhesives can release vary fast and leaves almost no residue on the surface. Moreover, the de-bonding temperature can be conveniently tuned according to practical needs.

### SUMMARY OF THE PRESENT INVENTION

One object of the present invention is to provide de-bondable polyurethane adhesives for the de-bonding of bonded surfaces without the problems listed above. This object is fulfilled by de-bondable polyurethane adhesives based on thermally expandable microspheres, obtainable or obtained by the reaction of the following components:
(A) at least one di- or polyisocyanate;
(B) at least one polyol;
(C) catalyst
(D) thermally expandable microspheres; and
(E) other additives,
   wherein the isocyanate index of the reaction is set in the range of from 28 to 65.

In an embodiment, the isocyanate index of the reaction is set in the range of from 30 to 60, preferably from 30 to 50, more preferably from 35 to 50.

In a further embodiment, the polyol (B) is selected from polyetherols and/or polyesterols having from 2 to 8 hydrogen atoms reactive toward isocyanate.

In another embodiment, the de-bonding time of the polyurethane adhesive in hot water under temperature of 75° C. or above is less than 10 minutes.

The present invention also provides a process for preparing the de-bondable polyurethane adhesives based on thermally expandable microspheres, comprising the step of mixing the above components, wherein the isocyanate index of the reaction is set in the range of from 28 to 65.

The present invention further relates to the use of the de-bondable polyurethane adhesives based on thermally expandable microspheres for de-bonding metal and cutting pad during wafer cutting, and use of the de-bondable polyurethane adhesives based on thermally expandable microspheres in mechanical property testing sample preparation.

Compared with conventional adhesives, the inventive de-bondable polyurethane adhesives can achieve the de-bonding of bonded surfaces in hot water more efficiently and cleanly, with little or no residue left on the surface or no odor problem. Moreover, the de-bonding time and de-bonding temperature can be well controlled by adjusting the composition and mixing ratio of the adhesives.

### BRIEF DESCRIPTION OF THE DRAWINGS

FIG. 1 is a schematic view of a typical wafer cutting process, in which the polyurethane adhesive is used for the de-bonding of the metal plate and the cutting pad in step 4.

FIG. 2 is the depiction of specific thermally expandable microspheres, with 2(a) SEM photo of the microspheres, 2(b) planar view of the microspheres, and 2(c) inner structure of the microspheres.

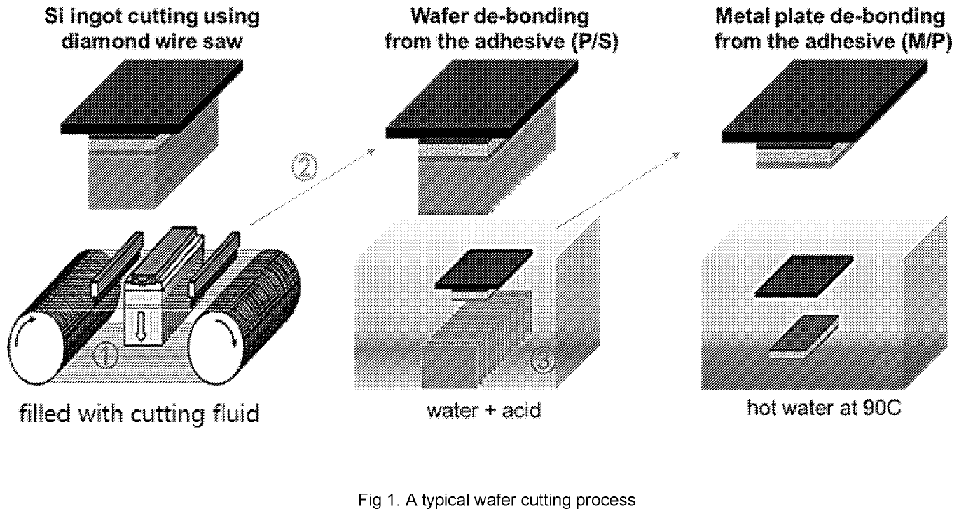

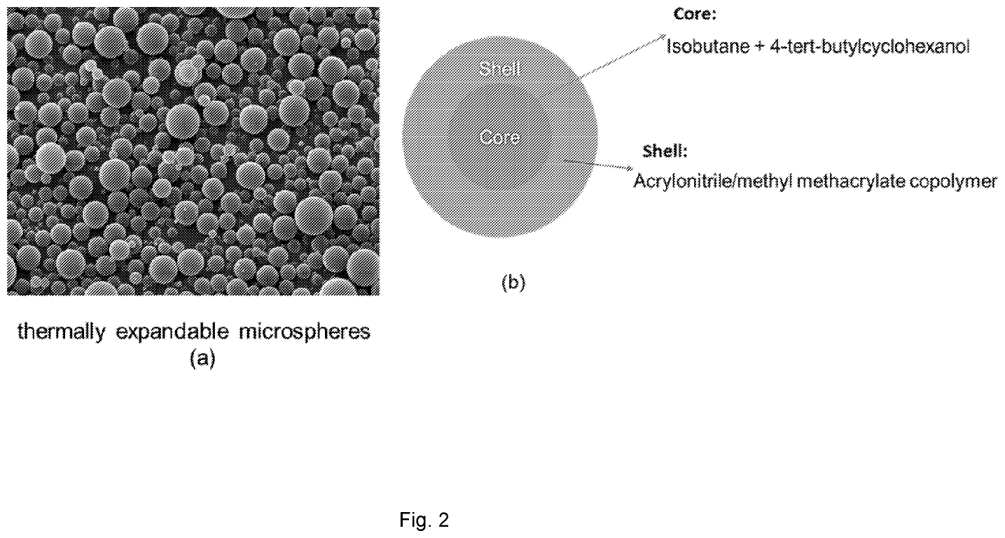

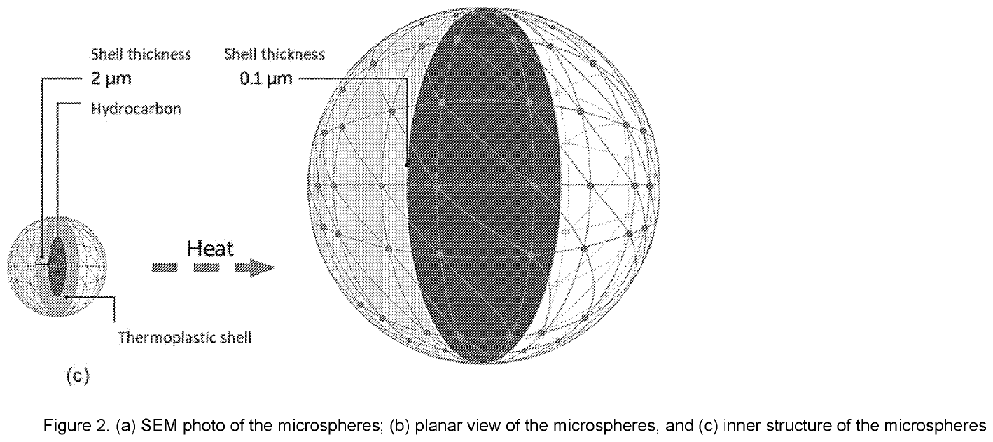

### DETAILED DESCRIPTION OF THE PRESENT INVENTION

Unless defined otherwise, all technical and scientific terms used herein have the meaning commonly understood by a person skilled in the art to which the invention belongs. As used herein, the following terms have the meanings ascribed to them below, unless specified otherwise.

As used herein, the articles “a” and “an” refer to one or to more than one (i.e., to at least one) of the grammatical object of the article. By way of example, “an element” means one element or more than one element.

As used herein, the term “about” is understood to refer to a range of numbers that a person of skill in the art would consider equivalent to the recited value in the context of achieving the same function or result.

As used herein, the term “additives” refers to additives included in a formulated system to enhance physical or chemical properties thereof and to provide a desired result. Such additives include, but are not limited to, dyes, pigments, toughening agents, impact modifiers, rheology modifiers, plasticizing agents, thixotropic agents, natural or synthetic rubbers, filler agents, reinforcing agents, thickening agents, inhibitors, fluorescence or other markers, thermal degradation reducers, thermal resistance conferring agents, surfactants, wetting agents, defoaming agents, dispersants, flow or slip aids, biocides, and stabilizers.

Unless otherwise identified, all percentages (%) are “percent by weight”.

The radical definitions or elucidations given above in general terms or within areas of preference apply to the end products and correspondingly to the starting materials and intermediates. These radical definitions can be combined with one another as desired, i.e. including combinations between the general definition and/or the respective ranges of preference and/or the embodiments.

All the embodiments and the preferred embodiments disclosed herein can be combined as desired, which are also regarded as being covered within the scope of the present invention.

Unless otherwise identified, the temperature refers to room temperature and the pressure refers to ambient pressure.

Unless otherwise identified, the solvent refers to all organic and inorganic solvents known to the persons skilled in the art and does not include any type of monomer molecular.

The present invention is directed to de-bondable polyurethane adhesives based on thermally expandable microspheres, obtainable or obtained by the reaction of the following components:
(A) at least one di- or polyisocyanate;
(B) at least one polyol;
(C) catalyst
(D) thermally expandable microspheres; and
(E) other additives,
   wherein the isocyanate index of the reaction is in the range of from 28 to 65.

### Di- or Polyisocyanate (A)

The di- or polyisocyanates (A) used can be any of the aliphatic, cycloaliphatic, or aromatic isocyanates known for producing polyurethanes. Aliphatic diisocyanates used are customary aliphatic and/or cycloaliphatic diisocyanates, for example tri-, tetra-, penta-, hexa-, hepta- and/or octamethylene diisocyanate, 2-methylpentamethylene 1,5-diisocyanate, 2-ethyltetramethylene 1,4-diisocyanate, hexamethylene 1,6-diisocyanate (HDI), pentamethylene 1,5-diisocyanate, butylene 1,4-diisocyanate, trimethylhexamethylene 1,6-diisocyanate, 1-isocyanato-3,3,5-trimethyl-5-isocyanatomethylcyclohexane (isophorone diisocyanate, IPDI), 1,4- and/or 1,3-bis(isocyanatomethyl)cyclohexane (HXDI), cyclohexane 1,4-diisocyanate, 1-methylcyclohexane 2,4- and/or 2,6-diisocyanate, methylene dicyclohexyl 4,4′-, 2,4′- and/or 2,2′-diisocyanate (H12MDI). Suitable aromatic diisocyanates are especially naphthylene 1,5-diisocyanate (NDI), tolylene 2,4- and/or 2,6-diisocyanate (TDI), 3,3′-dimethyl-4,4′-diisocyanatodiphenyl (TODI), p-phenylene diisocyanate (PDI), diphenylethane 4,4′-diisocyanate (EDI), diphenylmethane diisocyanate, dimethyl diphenyl 3,3′-diisocyanate, diphenylethane 1,2-diisocyanate and/or diphenylmethane diisocyanates (MDI).

The di- or polyisocyanates (A) used preferably comprise isocyanates based on diphenylmethane diisocyanate, in particular comprising polymeric MDI. The functionality of the di- and polyisocyanates (A) is preferably from 2.0 to 2.9, particularly preferably from 2.1 to 2.8. The viscosity of the di- or polyisocyanates (a) at 25° C. to DIN 53019-1 to 3 here is preferably from 5 to 600 mPas and particularly preferably from 10 to 300 mPas.

Di- and polyisocyanates (A) can also be used in the form of polyisocyanate prepolymers. These polyisocyanate prepolymers are obtainable by reacting an excess of the polyisocyanates described above (constituent (a-1)) with compounds (constituent (a-2)) having at least two groups reactive toward isocyanates, for example at temperatures of from 30 to 1000° C., preferably at about 80° C., to give the prepolymer. The NCO content of polyisocyanate prepolymers of the invention is preferably from 20 to 33% by weight of NCO, particularly preferably from 25 to 32% by weight of NCO.

In a preferred embodiment, the di- or polyisocyanates (A) are selected from 2,2′-MDI, 4,4′-MDI, MDI prepolymer, or the mixture thereof.

The di- or polyisocyanates (A) may be present in the polyurethane adhesives in an amount of from 25 to 70 wt %, preferably 30 to 65 wt %, more preferably 35 to 60 wt %, based on the total weight of the polyurethane adhesives.

### Polyol (B)

polyol (B) used herein can be any of the aliphatic, cycloaliphatic, or aromatic polyols known for producing polyurethanes. It is preferred to use polyetherols and/or polyesterols having from 2 to 8 hydrogen atoms reactive toward isocyanate. The OH number of these compounds is usually in the range from 20 to 2000 mg KOH/g, preferably in the range from 40 to 1000 mg KOH/g. The average OH number of all of the compounds (B) used here having at least two groups reactive toward isocyanates is from 100 to 1000 mg KOH/g, preferably from 200 to 900 mg KOH/g. The polyols may have a molecular weight Mw of 200 to 50000 g/mol, preferably 400 to 8000 g/mol.

The polyetherols are obtained by known processes, for example via anionic polymerization of alkylene oxides with addition of at least one starter molecule comprising from 2 to 8, preferably from 2 to 6, and particularly preferably from 2 to 4, reactive hydrogen atoms, in the presence of catalysts. Catalysts used can comprise alkali metal hydroxides, such as sodium hydroxide or potassium hydroxide, or alkali metal alcoholates, such as sodium methoxide, sodium ethoxide, potassium ethoxide, or potassium isopropoxide, or, in the case of cationic polymerization, Lewis acids, such as antimony pentachloride, boron trifluoride etherate, or bleaching earth. Other catalysts that can be used are double-metal cyanide compounds, known as DMC catalysts.

The alkylene oxides used preferably comprise one or more compounds having from 2 to 4 carbon atoms in the alkylene moiety, e.g. tetrahydrofuran, ethylene oxide, propylene 1,2-oxide, butylene 1,2-oxide or butylene 2,3-oxide, in each case alone or in the form of a mixture, and preferably propylene 1,2-oxide and/or ethylene oxide, in particular propylene 1,2-oxide.

Examples of starter molecules that can be used are ethylene glycol, diethylene glycol, glycerol, trimethylolpropane, pentaerythritol, sugar derivatives, such as sucrose, hexitol derivatives, such as sorbitol, methylamine, ethylamine, isopropylamine, butylamine, benzylamine, aniline, toluidine, toluenediamine, naphthylamine, ethylenediamine, diethylenetriamine, 4,4′-methylenedianiline, 1,3-propanediamine, 1,6-hexanediamine, ethanolamine, diethanolamine, triethanolamine, and also other di- or polyhydric alcohols, or di- or polybasic amines.

The polyesterols used are mostly produced via condensation of polyhydric alcohols having from 2 to 12 carbon atoms, e.g. ethylene glycol, diethylene glycol, butanediol, trimethylolpropane, glycerol, or pentaerythritol, with polybasic carboxylic acids having from 2 to 12 carbon atoms, e.g. succinic acid, glutaric acid, adipic acid, suberic acid, azelaic acid, sebacic acid, decanedicarboxylic acid, maleic acid, fumaric acid, phthalic acid, isophthalic acid, terephthalic acid, and the isomers of naphthalenedicarboxylic acids, or their anhydrides.

Other starting materials that can also be used concomitantly in producing the polyesterols are hydrophobic substances. The hydrophobic substances are substances insoluble in water which comprise a nonpolar organic moiety, and which also have at least one reactive group selected from hydroxyl, carboxylic acid, carboxylic ester, or a mixture thereof. The equivalent weight of the hydrophobic materials is preferably from 130 to 1000 g/mol. Examples of materials that can be used are fatty acids, such as stearic acid, oleic acid, palmitic acid, lauric acid, or linoleic acid, and also fats and oils, e.g. castor oil, maize oil, sunflower oil, soybean oil, coconut oil, olive oil, or tall oil. If polyesters comprise hydrophobic substances, the proportion of the hydrophobic substances, based on the total monomer content of the polyester alcohol, is preferably from 1 to 30 mol %, particularly preferably from 4 to 15 mol %.

The functionality of the polyesterols used is preferably from 1.5 to 5, particularly preferably from 1.8 to 3.5.

In one particularly preferred embodiment, the polyols (B) having groups reactive toward isocyanates comprise polyetherols, in particular exclusively polyetherols. The actual average functionality of the polyetherols is preferably from 2 to 4, particularly preferably from 2.5 to 3.5, in particular from 2.8 to 3.2, and their OH number is preferably from 20 to 900 mg KOH/g, and their content of secondary OH groups is preferably at least 50%, with preference at least 60%, with particular preference at least 70% and in particular at least 80%. The polyetherol used here preferably comprises polyetherol based on glycerol as starter and on propylene-1,2-oxide.

The polyol (B) may be present in the polyurethane adhesives in an amount of from 15 to 45 wt %, preferably 18 to 40 wt %, more preferably 25 to 35 wt %, based on the total weight of the polyurethane adhesives.

### Catalyst (C)

The polyurethane catalyst can comprise any of the catalysts conventional for producing polyurethane. These catalysts are described by way of example in “Polyurethane Handbook” Carl Hanser Verlag, 2nd edition 1993, chapter 3.4.1. Examples of those that can be used here are organometallic compounds, such as complexes of tin, of zinc, of titanium, of zirconium, of iron, of mercury, or of bismuth, preferably organotin compounds, such as stannous salts of organic carboxylic acids, e.g. stannous acetate, stannous octoate, stannous ethylhexanoate, and stannous laurate, and the dialkyltin(IV) salts of carboxylic acids, e.g. dibutyltin diacetate, dibutyltin dilaurate, dibutyltzin maleate, and dioctyltin diacetate, and also phenylmercury neodecanoate, bismuth carboxylates, such as bismuth(Ill) neodecanoate, bismuth 2-ethylhexanoate, and bismuth octanoate, or a mixture. Other possible catalysts are basic amine catalysts. Examples of these are amidines, such as 2,3-dimethyl-3,4,5,6-tetrahydropyrimidine, tertiary amines, such as triethylamine, triethylenediamine, tributylamine, dimethylbenzylamine, N-methyl, N-ethyl, N-cyclohexylmorpholine, N,N,N′,N′-tetramethylethylenediamine, N,N,N′,N′-tetramethylbutanediamine, N,N,N′,N′-tetramethylhexanediamine, penta-methyldiethylenetriamine, tetramethyldiaminoethyl ether, bis(dimethylamino-propyl)urea, dimethylpiperazine, 1,2-dimethylimidazole, 1-azabicyclo[3.3.0]octane, and preferably 1,4-diazabicyclo[2.2.2]octane, 1,8-diazabicyclo[5.4.0]-undecen-7-ene, and alkanolamine compounds, such as triethanolamine, triisopropanolamine, N-methyl- and N-ethyldiethanolamine, and dimethylethanolamine. The catalysts can be used individually or in the form of a mixture. Mixtures of metal catalysts and of basic amine catalysts are optionally used as catalysts (c).

These catalysts hasten the reaction of compounds having isocyanate-reactive hydrogen atoms with di- and polyisocyanates to a substantial extent. Preferred catalysts for preparing the polyurethanes include, for example, amidines, such as 2,3-dimethyl-3,4,5,6-tetrahydropyrimidine, tertiary amines, such as triethylamine, tributylamine, dimethylbenzylamine. Also preferred are organometallic compounds, preferably organotin compounds, such as tin(II) salts of organic carboxylic acids, e.g., tin(II) acetate, tin(II) octoate, tin(II) ethylhexoate and tin(II) laurate.

The catalyst (C) may be present in the polyurethane adhesives in an amount of from 0.01 to 2 wt %, preferably 0.05 to 1 wt %, more preferably 0.1 to 0.5 wt %, based on the total weight of the polyurethane adhesives.

### Thermally Expandable Microspheres (D)

Thermally expandable microspheres (D) that can be used in the present invention typically have a core-shell structure, wherein the shell is formed of cross-linked polymer and the core is mainly composed of blowing agent. As to the polymer, it can be prepared by (co)polymerization of any suitable monomers or comonomers. Suitable monomer that can be used for preparing the polymer includes nonionic ethylenically unsaturated monomers. Possible nonionic ethylenically unsaturated monomers that can be used are for example styrene, vinyltoluene, ethylene, butadiene, vinyl acetate, vinyl chloride, vinylidene chloride, acrylonitrile, acrylamide, methacrylamide, (C₁-C₂₀)alkyl or (C₃-C₂₀)alkenyl esters of acrylic or methacrylic acid, methacrylate, methyl methacrylate, ethyl acrylate, ethyl methacrylate, butyl acrylate, butyl methacrylate, 2-ethylhexyl acrylate, 2-ethylhexyl methacrylate, benzyl acrylate, benzyl methacrylate, lauryl acrylate, lauryl methacrylate, oleyl acrylate, oleyl methacrylate, palmityl acrylate, palmityl methacrylate, stearyl acrylate, stearyl methacrylate, hydroxyl-containing monomers, in particular C₁-C₁₀ hydroxyalkyl (meth)acrylates, such as hydroxyethyl (meth)acrylate, hydroxypropyl (meth)acrylate, glycidyl (meth)acrylate, preferably methyl methacrylate.

Particularly, the polymer may be a copolymer prepared by the copolymerization of two or more monomers listed above. Preferable combination of monomers includes acrylonitrile/methyl (meth)acrylate, styrene/methyl (meth)acrylate, acrylamide/methyl (meth)acrylate, acrylonitrile/hydroxyethyl (meth)acrylate, etc. Most preferably used combination is acrylonitrile/methyl methacrylate.

Crosslinking agent that can be used for the crosslinking of the polymer are compounds having two or more ethylenically unsaturated groups, for example diacrylates or dimethacrylates of at least dihydric saturated alcohols, e.g., ethylene glycol diacrylate, ethylene glycol dimethacrylate, 1,2-propylene glycol diacrylate, 1,2-propylene glycol dimethacrylate, 1,4-butanediol diacrylate, 1,4-butanediol dimethacrylate, hexanediol diacrylate, hexanediol dimethacrylate, neopentylglycol diacrylate, neopentylglycol dimethacrylate, 3-methylpentanediol diacrylate and 3-methylpentanediol dimethacrylate. A further class of crosslinkers comprises diacrylates or dimethacrylates of polyethylene glycols or polypropylene glycols having molecular weights of 200 to 9000 in each case. Polyethylene and/or polypropylene glycols used for preparing the diacrylates or dimethacrylates preferably have a molecular weight of 400 to 2000 each. Not only the homopolymers of ethylene oxide and/or propylene oxide can be used, but also block copolymers of ethylene oxide and propylene oxide, or random copolymers of ethylene oxide and propylene oxide, which comprise a random distribution of the ethylene oxide and propylene oxide units. Similarly, the oligomers of ethylene oxide and/or propylene oxide are useful for preparing the crosslinkers, examples being diethylene glycol diacrylate, diethylene glycol dimethacrylate, triethylene glycol diacrylate, triethylene glycol dimethacrylate, tetraethylene glycol diacrylate and/or tetraethylene glycol dimethacrylate.

Crosslinkers are preferably used in amounts of 0.1 to 30 wt %, based on the monomers to be polymerized in any one stage. Crosslinkers may be added in every stage.

The core is preferably composed of physical blowing agent. Suitable physical blowing agent includes alkanes and/or cycloalkanes with at least 4 carbon atoms, dialkyl ethers, esters, ketones, acetals, fluoroalkanes with 1 to 8 carbon atoms, and tetraalkylsilanes with 1 to 3 carbon atoms in the alkyl chain, in particular tetramethylsilane.

In one preferred embodiment of the invention, the physical blowing agents are hydrocarbons. Particularly preferably, the physical blowing agents are selected from the group comprising alkanes and/or cycloalkanes with at least 4 carbon atoms. In particular, pentanes, preferably isopentane and cyclopentane, are used. With the use of the rigid foams as insulation in cooling appliances, cyclopentane is preferred. The hydrocarbons can be used in mixture with water.

As examples of blowing agents usable according to the invention, propane, n-butane, iso- and cyclobutane, n-, iso- and cyclopentane, cyclohexane, dimethyl ether, methyl ethyl ether, methyl butyl ether, methyl formate and acetone may be mentioned, and also fluoroalkanes which can be degraded in the troposphere and thus are harmless to the ozone layer, such as trifluoromethane, difluoromethane, 1,1,1,3,3-pentafluorobutane, 1,1,1,3,3-pentafluoropropane, 1,1,1,2-tetrafluoroethane, difluoroethane and 1,1,1,2,3,3,3-heptafluoropropane, and perfluoroalkanes such as C₃F₈, C₄F₁₀, C₅F₁₂, C₆F₁₄ and C₇F₁₆. The said blowing agents can be used alone or in any combination with one another.

Further, hydrofluoro olefins, such as 1,3,3,3-tetrafluoropropene, or hydrochlorofluoro olefins, such as 1-chloro-3,3,3-trifluoropropene, can be used as blowing agents. Such blowing agents are for example described in WO 2009/048826.

The thermally expandable microspheres can be prepared by seed swelling of the crosslinked polymer and encapsulation of the blowing agents. The microspheres thus formed have a diameter of 5-40 μm, preferably 10-20 μm, with the shell having a thickness of 0.5 to 10 μm. When the adhesive is immersed in hot water under elevated temperature below 100° C., the thermally expandable microspheres expand with the physical blowing agent upon heating of the hot water. The diameter of the microspheres can be increased to as high as about 100 μm, and the thickness of the shell can decrease to as low as 0.1 μm. The thermally expandable microspheres may have a density of 3-20 kg/m³, preferably 5-12 kg/m³. Such thermally expandable microspheres can be commercially available as, for example, Expancel series from AkzoNobel Inc.

The thermally expandable microspheres may have a starting temperature Tₛₜₐᵣₜ of 75° C. or above. In an embodiment, the starting temperature Tₛₜₐᵣₜ of the thermally expandable microspheres is 75-97° C., preferably 80-95° C., more preferably 85-90° C. Starting temperature Tₛₜₐᵣₜ is the temperature on which the thermally expandable microspheres start to expand upon heating. Theoretically, the polyurethane adhesive starts to de-bond upon the expansion of the thermally expandable microspheres, and thus the temperature on which the adhesive starts to de-bond is equal to or above the starting temperature Tₛₜₐᵣₜ of the microspheres.

The thermally expandable microspheres (D) may be present in the polyurethane adhesives in an amount of from 2 to 20 wt %, preferably 3 to 12 wt %, more preferably 5 to 10 wt %, based on the total weight of the polyurethane adhesives.

### Other Additives (E)

As additives for the purpose of the present invention, substances known per se, for example, surfactants, foam stabilizers, pore regulators, fillers, pigments, dyes, flame retardants, antihydrolytic agents, antistatic agents, water absorbents, and agents with fungistatic and bacteriostatic action may be used.

In a preferred embodiment, the present invention provides de-bondable polyurethane adhesives based on thermally expandable microspheres, obtainable or obtained by the reaction of the following components:
(A) 25-70 wt % of at least one di- or polyisocyanate;
(B) 15-45 wt % of at least one polyol;
(C) 0.01-2 wt % of catalyst
(D) 2-20 wt % of thermally expandable microspheres; and
(E) other additives, based on the total weight of the polyurethane adhesives,
   wherein the isocyanate index of the reaction is set in the range of from 30 to 60.

The present invention also provides a process for preparing the de-bondable polyurethane adhesives based on thermally expandable microspheres, comprising the step of mixing the following components:
(A) at least one di- or polyisocyanate;
(B) at least one polyol;
(C) catalyst
(D) thermally expandable microspheres; and
(E) other additives,
   wherein the isocyanate index is set to be in the range of from 28 to 65.

In an embodiment, the polyurethane adhesive thus formed has a density of 0.8-1.5 g/cm³, preferably 1.0-1.2 g/cm³. Suitable production processes for polyurethane are also disclosed, for example, in EP 0922552 A1, DE 10103424 A1 or WO 2006/072461 A1. Depending on the material properties of the components, these are all mixed directly with each other or individual components are premixed and/or pre-reacted, for example, to prepolymers, and then brought to polyaddition. In a preferred embodiment, the di- or polyisocyanate (A) is added separately as component (ii), while the polyol (B), catalyst (C), thermally expandable microspheres (D) and other additives (E) form component (i) to be added together. The mixing ratio of component (i) to (ii) may be from 3:1 to 1:3, preferably 2.5:1 to 1:2, more preferably 2:1 to 1:1.8.

By adjusting reaction parameters such as the relative amount of each components, especially components (A) and (B), it is advantageous to set the isocyanate index for preparing the polyurethane adhesives to be from 28 to 65, preferably 30 to 60, more preferably from 30 to 50, and most preferably from 35 to 50. For conventional polyurethanes, the isocyanate index for the preparation thereof is normally set to be around 100, such as 95-104. Surprisingly, the present inventors have found that, in the present invention, the de-bonding efficiency is highly dependent on the index of the polyurethane adhesives, and relatively low index is a key technical point for these adhesives to allow de-bonding of the bonded surfaces in hot water.

Thus, the present invention also relates to use of the de-bondable polyurethane adhesives based on thermally expandable microspheres for de-bonding metal and cutting pad during wafer cutting. The wafer may be any semiconductor raw materials, such as Si, Ga, Ge, GaN, GaAs or the like. Such polyurethane adhesives can have strong adhesion properties between metal and cutting pad (epoxy, PU rigid foam, etc.) under various cutting conditions (high vibration, constant water spray, and long term stability in 70° C. acid water), while having efficient de-bonding performance in water under elevated temperature (75° C. or above, 80° C. or above, or close to boiling point). Thus, when the bonded metal plate and cutting pad are immersed in hot water of, for example, 75° C., 80° C., 85° C., 90° C., or 97° C., the polyurethane adhesives expand along with the expanding of the incorporated microspheres, and release from the metal surface efficiently and cleanly, leaving little or no residue on the metal surface, in a short time. The de-bonding time of the adhesives can be well controlled and tuned by adjusting the isocyanate index for preparing the polyurethane adhesives, and desired de-bonding performance can thus be achieved.

Moreover, the present invention relates to use of the de-bondable polyurethane adhesives based on thermally expandable microspheres in mechanical property testing sample preparation. Conventionally, when performing the mechanical property, such as tensile strength, test of a sample, the sample is fixed by a clamp, which would easily cause fractures, or other defects on the sample. The de-bondable polyurethane adhesives according to the present invention can be applied to the metal fixture used for fixating a sample to the testing equipment, and the testing specimen is adhered to the fixture using the de-bondable adhesive. The de-bondable adhesive according to the present invention can provide satisfied bonding between the testing specimen and the testing fixture. After the tensile test, the testing specimen can be easily removed from the testing fixture by placing the sample in a hot water bath of elevated temperature, which temperature can be tuned by adjusting the composition or index of the adhesives, such as under the temperature of 75° C., 80° C., 85° C., 90° C., or 95° C.

The de-bondable polyurethane adhesives based on thermally expandable microspheres provide multiple advantages. For example, the adhesives can be released in a high efficiency, and little or no residual is left on the substrate surface. This would help save processing time in the wafer cutting process. The release temperature can be well controlled and tuned by adjusting the composition and the index of the polyurethane adhesives. Moreover, the inventive polyurethane adhesives have no problem concerning odor owing to the fact that epoxy adhesives conventionally used in the prior art can be omitted. Additionally, faster release at the de-bonding temperature can be achieved. The de-bonding time can be as low as 1-2 minutes, which significantly improves the efficiency of the cutting process as compared with conventional de-bonding procedure which often lasts for, for example, more than one hour.

### EXAMPLES

The present invention will now be described with reference to Examples and Comparative Examples, which are not intended to limit the present invention.

The following materials were used:
Isocyanate A: Elastan Iso 6572-101 C-B, 4,4′-MDI prepolymer commercially available from BASF, with a NCO value of about 17.6.
Polyol 1: PO-based glycerol-initiated polyols, with Mw of about 6000 and an OH number of about 27 mg KOH/g.
Polyol 2: EO-based glycerol-initiated polyols, with Mw of about 400 and an OH number of about 400 mg KOH/g.
Catalyst: Dabco 33LV, solution of 33% of triethylene diamine in propylene glycol, commercially available from Air Products.
Thermally expandable microspheres (TEMs): spherical plastic core-shell structure particles with the particle size of 10-16 μm, wherein the hydrocarbon (foaming agent) is encapsulated by a cross-linked acrylonitrile/methyl methacrylate copolymer network shell, and the Tₛₜₐᵣₜ=80-95° C.
T-paste: Castor Oil with 50% Zeolite, water absorbent.
Filler: MgSiO₃

### Measurement Methods:

### Lap Shear Test

Clean the substrate surface with ethanol and dry for 5 minutes. Stainless steel plate is Q-Panel RS-14, obtained from Q-Lab. Mix the component (i) and component (ii) with a spatula or in a mixer for 45 sec and then apply on the substrate surfaces. Application area is 12.5 mm*25 with a thickness of 0.2 mm. Clamp on the samples with a 4 kg clamp and remove residual adhesive. After 4 hr of curing at room temperature, conduct lap shear test at 200 mm/min. Replicate sample testing 5 times.

### De-Bonding Test in Lactic Acid Solution

Follow the same procedure for sample preparation of lap shear test. After 5 hr of room temperature curing, place the sample into a 10% lactic acid solution at 70° C. Observe if there is adhesive failure after 1 hr of immersion. Replicate the sample testing 3 times.

### De-Bonding Test in Citric Acid Solution

Follow the same procedure for sample preparation of lap shear test. After 5 hr of room temperature curing, place the sample into a 5% citric acid solution at 80° C. Observe if there is adhesive failure after 1 hr of immersion. Replicate the sample testing 3 times.

### De-Bonding Test in Boiling Water

Follow the same procedure for sample preparation of lap shear test. After 6 hr of room temperature curing, place the sample into a 97° C. Water. Observe and record adhesive failure time. Replicate the sample testing 3 times.

### Viscosity

Test the adhesive viscosity following the procedure W00034, using HAAKE Viscometer

### Gel Time

Turn on the gel timer (Brookfield Gel Timer DV2T) and mix the A and B Components with a spatula for 45 sec. Put into the gel timer and start recording time until the spinner cannot rotate. Record the stop time as gel time.

### Fix Time

Mix the A and B Components with a spatula for 45 sec and prepare lap shear sample. After sample is prepared, check the lap shear sample constantly and record the time when the two substrates stop slipping as the fix time.

### Example 1

24.5 parts of polyol 1, 25 parts of polyol 2, 4.9 parts of glycerin, 5 parts of T-paste, 0.132 parts of Dabco 33LV, 20 parts of filler, and 10 parts of TEMs were weighed out as component (i) in a 100 ml PP cup. Then, weighed out isocyanate A as component (ii) according to a mixing ratio (component (i):component (ii)) by weight of 100:49 and added quickly into the cup. After sealing the cup with a lid having a pinhole (for vacuum purpose), the cup was placed in a speed mixer to mix under vacuum for 2 min at 1500 rpm. Then the mixture was applied on the substrate surfaces and tested for properties as stated above.

### Examples 2-4

In examples 2-4, the preparation procedure was the same as in example 1, except that the components used were added in the amounts as set forth in table 1.

### Comparative Example 1

In comparative example 1, the preparation procedure was the same as in example 1, except that the components used were added in the amounts as set forth in table 1. Particularly, no TEMs was added into the reaction mixture.

The properties of the adhesive samples produced from examples 1-4 and comparative examples 1-2 were tested and the results were summarized in the following table 1.

TABLE 1
Properties of the adhesive samples according to the
inventive examples 1-4 and comparative examples 1-2

| | comparative | | | | |
|---|---|---|---|---|---|
| | example 1 | example 1 | example 2 | example 3 | example 4 |
| Polyol 1 | 24.5 | 24.5 | 20 | 24.5 | 24.5 |
| Polyol 2 | 25 | 25 | 30 | 25 | 25 |
| Glycerin | 4.9 | 4.9 | 7.5 | 9.9 | 9.9 |
| T-paste | 5 | 5 | 5 | 5 | 5 |
| Dabco 33LV | 0.132 | 0.132 | 0.36 | 0.48 | 0.48 |
| Filler | 40 | 20 | 40 | 40 | 50 |
| TEMs | | 10 | 10 | 10 | 10 |
| Sum of | 99.532 | 89.532 | 112.86 | 114.88 | 124.88 |
| Component (i) | | | | | |
| Isocyanate A | 100 | 100 | 100 | 100 | 100 |
| Component (ii) | | | | | |
| Mixing ratio | 100:49 | 100:54.5 | 100:50 | 100:50 | 100:50 |
| Component (i):Component (ii) | | | | | |
| (by weight) | | | | | |
| Index | 52.7 | 52.7 | 45.9 | 42.6 | 46.5 |
| 4 h lap shear | 5.03 | 4.57 | 6.64 | 5.23 | 7.23 |
| strength (MPa) | | | | | |
| 10% lactic acid in | No Failure | No Failure | No Failure | No Failure | No Failure |
| water (70° C.) | | | | | |
| 97° C. hot water | >60 | 2.5 | 1.1 | 1.4 | 1.7 |
| de-bonding(min) | | | | | |
| Gel time (min) | 10′52″ | 12′5″ | 4′51″ | 7′35″ | 4′49″ |
| Fix time (min) | 80 | 80 | 26 | 55 | 25 |
| Viscosity (mPa · s) | 4981 | 4944 | 8698 | 8373 | 12300 |

All the adhesive samples prepared show strong adhesion property in lap shear test and good stability in acid/water solution. Nevertheless, comparative example 1 includes no thermally expandable microspheres in the reaction mixture, and thus the adhesives sample prepared therein shows a de-bonding time of more than 60 minutes in 97° C. hot water, which is unacceptable for the de-bonding procedure in the wafer cutting process. In contrast, all inventive adhesive samples exhibit excellent de-bonding performance in less than 3 minutes in 97° C. hot water. It is also to be noted that, the de-bonding efficiency is highly dependent on the index of the adhesives. Even for inventive samples with index falling within the inventive range, an isocyanate index of 40-50 seems to produce better results in terms of de-bonding time.

### Examples 5-7

In examples 5-7, the preparation procedure was the same as in example 1, except that the components used were added in the amounts as set forth in table 2. By adjusting the added amounts of each components, and the mixing ratio of components (i) and (ii), certain isocyanate index was achieved for the corresponding example as shown in table 2. After mixing, the mixture was applied on the substrate surfaces and tested for properties as stated above.

### Comparative Examples 2-6

In comparative examples 2-6, the preparation procedure was the same as in example 1, except that the components used were added in the amounts as set forth in table 2. By adjusting the added amounts of each components, and the mixing ratio of components (i) and (ii), certain isocyanate index was achieved for the corresponding example as shown in table 2. After mixing, the mixture was applied on the substrate surfaces and tested for properties as stated above.

The properties of the adhesive samples produced from examples 5-7 and comparative examples 2-6 were tested and the results were summarized in the following table 2.

TABLE 2
Properties of the adhesive samples according to the
inventive examples 5-7 and comparative examples 2-6

| | comparative | | | |
|---|---|---|---|---|
| | example 2 | example 5 | example 6 | example 7 |
| Polyol 1 | 24.5 | 24.5 | 24.5 | 24.5 |
| Polyol 2 | 25 | 25 | 25 | 25 |
| glycerin | 7.5 | 7.5 | 7.5 | 7.5 |
| T-paste | 5 | 5 | 5 | 5 |
| Dabco 33LV | 0.30 | 0.30 | 0.30 | 0.30 |
| Filler | 20 | 20 | 20 | 20 |
| TEMs | 10 | 10 | 10 | 10 |
| Sum of | 92.3 | 92.3 | 92.3 | 92.3 |
| component (i) | | | | |
| Isocyanate A | 100 | 100 | 100 | 100 |
| Component (ii) | | | | |
| Mixing ratio | 100:30.3 | 100:36.4 | 100:50 | 100:72.8 |
| Component (i):Component (ii) | | | | |
| (by weight) | | | | |
| Index | 25 | 30 | 40.3 | 60 |
| 4 h lap shear | Cannot Cure | 1.05 | 3.85 | >7.5 |
| strength/MPa | | | | |
| 97° C. hot water | Cannot Cure | 45 sec | 1.25 min | 10.5min |
| de-bonding time (6 h) | | | | |

| | comparative | comparative | comparative | comparative |
|---|---|---|---|---|
| | example 3 | example 4 | example 5 | example 6 |
| Polyol 1 | 24.5 | 24.5 | 24.5 | 24.5 |
| Polyol 2 | 25 | 25 | 25 | 25 |
| glycerin | 7.5 | 7.5 | 7.5 | 7.5 |
| T-paste | 5 | 5 | 5 | 5 |
| Dabco 33LV | 0.30 | 0.30 | 0.30 | 0.30 |
| Filler | 20 | 20 | 20 | 20 |
| TEMs | 10 | 10 | 10 | 10 |
| Sum of | 92.3 | 92.3 | 92.3 | 92.3 |
| component (i) | | | | |
| Isocyanate A | 100 | 100 | 100 | 100 |
| Component (ii) | | | | |
| Mixing ratio | 100:91.0 | 100:109.2 | 100:145.6 | 100:182 |
| by wt. % | | | | |
| Index | 75 | 90 | 120 | 150 |
| 4 h lap shear | >7.5 | >7.5 | >7.5 | >7.5 |
| strength /MPa | | | | |
| 97° C. hot water | >25 min | >25 min | >25 min | >25 min |
| de-bonding time | | | | |
| (6 h) | | | | |

As can be seen from the above table 2, inventive examples 5-7 and comparative examples 2-6 used identical component (i) (i.e., mixture of components (B)-(E)) and component (ii) (i.e., component (A)), but in different mixing ratios. By using different mixing ratio of components (i) to (ii), each example results in specific polyurethane adhesive with specific index as shown in table 2. The properties tested as shown in tale 2 indicate that, when the index of the reaction to prepare the polyurethane adhesive falls within appropriate range, adhesive samples with desired lap shear strength and short de-bonding time in 97° C. hot water have been obtained. In contrast, if the index is too low, such as 25, the reaction mixture to form the polymer cannot cure, and no adhesive sample can be obtained, as seen in comparative example 2. On the other hand, if the index is too high, such as 75, 90 or above 100, the adhesive samples obtained required very long de-bonding time upon heating in 97° C. hot water, as seen from comparative examples 3-6. The de-bonding time can be as long as more than 25 minutes in these comparative examples, which time, though still being valid theoretically, is not commercially viable.

### Examples 8-10

In examples 8-10, the preparation procedure was the same as in example 6, except that the TEMs (0) were added in the amounts as set forth in table 3. By adjusting the added amounts of each components, and the mixing ratio of components (i) and (ii), certain isocyanate index was achieved for the corresponding example as shown in table 3. After mixing, the mixture was applied on the substrate surfaces and tested for properties as stated above.

### Comparative Example 7

In comparative example 7, the preparation procedure was the same as in example 6, except that the TEMs (0) were added in the amounts as set forth in table 3. After mixing, the mixture was applied on the substrate surfaces and tested for properties as stated above.

The properties of the adhesive samples produced from examples 8-10 and comparative example 7 were tested and the results were summarized in the following table 3, and compared with the results of example 6.

TABLE 3
Properties of the adhesive samples according to the inventive
examples 6 and 8-10 and comparative example 7

| | | | | | comparative |
|---|---|---|---|---|---|
| | example 6 | example 8 | example 9 | example 10 | example 7 |
| Polyol 1 | 24.5 | 24.5 | 24.5 | 24.5 | 24.5 |
| Polyol 2 | 25 | 25 | 25 | 25 | 25 |
| Glycerin | 7.5 | 7.5 | 7.5 | 7.5 | 7.5 |
| T-paste | 5 | 5 | 5 | 5 | 5 |
| Dabco 33LV | 0.30 | 0.30 | 0.30 | 0.30 | 0.30 |
| Filler | 20 | 20 | 20 | 20 | 20 |
| TEMs | 10 | 8 | 6 | 4 | 1 |
| Sum of | 92.3 | 90.3 | 88.3 | 86.3 | 83.3 |
| component (i) | | | | | |
| Isocyanate A | 100 | 100 | 100 | 100 | 100 |
| Component (ii) | | | | | |
| Mixing ratio | 100:50 | 100:50 | 100:50 | 100:50 | 100:50 |
| by wt. % | | | | | |
| Index | 40.3 | 39.5 | 38.5 | 37.7 | 36.4 |
| 4h lap shear | 3.85 | 4.46 | 5.47 | 5.10 | 5.10 |
| strength/MPa | | | | | |
| 97° C. | 1.2 min | 3.8 min | 6.3 min | 13.5 min | >1 hr |
| hot water | | | | | |
| debonding time | | | | | |
| (6 h) | | | | | |
| Viscosity | 13780 | 9180 | 8307 | 6969 | 4589 |
| (mPa · s) | | | | | |

Inventive examples 6 and 8-10 and comparative example 7 used identical components and the same mixing ratio, except that the TEMs (component D) is present in different amounts in these examples. The results shown in table 3 indicate that the de-bonding time of the adhesive sample increases as the amount of the thermally expandable microspheres (D) decreasing. When the amount of the thermally expandable microspheres (D) is too low, the de-boding time of the adhesive sample can be more than 1 hr, and is not commercially viable.

### Example 11

The polyurethane adhesive according to the present invention was also tested for use in tensile testing sample preparation in this example. Specifically, weighing out 30 g of component (i) and 15 g of component (ii) and mixing it manually in a sample cup. The component (i) had the same composition as set forth in table 1 for example 3. Manually applying the adhesive on the first metal fixture using a spatula (approximately 0.2-0.3 mm thick). Placing the testing sample on the metal fixture with the adhesive and allowing it to cure under room temperature. Manually applying the adhesive on the second metal fixture using a spatula. Placing the second metal fixture on the testing sample and fixing it to the universal tensile tester (a Zwick). After the tensile testing was completed, placing the metal fixture into a 90° C. water bath. The metal fixture was easily detached from the sample in about 1-2.5 minutes and allowed to be easily reclaimed.

The structures, materials, compositions, and methods described herein are intended to be representative examples of the invention, and it will be understood that the scope of the invention is not limited by the scope of the examples. Those skilled in the art will recognize that the invention may be practiced with variations on the disclosed structures, materials, compositions and methods, and such variations are regarded as within the ambit of the invention. Thus, it is intended that the present invention cover such modifications and variations as come within the scope of the appended claims and their equivalents.

1. A de-bondable polyurethane adhesive based on thermally expandable microspheres, obtainable or obtained by the reaction of the following components:
(A) at least one di- or polyisocyanate;
(B) at least one polyol;
(C) catalyst;
(D) thermally expandable microspheres; and
(E) other additives,
wherein the isocyanate index of the reaction is set in the range of from 28 to 65.

2. The polyurethane adhesive according to claim 1, wherein the isocyanate index of the reaction is set in the range of from 30 to 60.

3. The polyurethane adhesive according to claim 1, wherein the di- or polyisocyanate (A) is selected from the group consisting of tri-, tetra-, penta-, hexa-, hepta- and/or octamethylene diisocyanate, 2-methylpentamethylene 1,5-diisocyanate, 2-ethyltetramethylene 1,4-diisocyanate, hexamethylene 1,6-diisocyanate (HDI), pentamethylene 1,5-diisocyanate, butylene 1,4-diisocyanate, trimethylhexamethylene 1,6-diisocyanate, 1-isocyanato-3,3,5-trimethyl-5-isocyanatomethylcyclohexane (isophorone diisocyanate, IPDI), 1,4- and/or 1,3-bis(isocyanatomethyl)cyclohexane (HXDI), cyclohexane 1,4-diisocyanate, 1-methylcyclohexane 2,4- and/or 2,6-diisocyanate, methylene dicyclohexyl 4,4′-, 2,4′- and/or 2,2′-diisocyanate (H12MDI), naphthylene 1,5-diisocyanate (NDI), tolylene 2,4- and/or 2,6-diisocyanate (TDI), 3,3′-dimethyl-4,4′-diisocyanatodiphenyl (TODI), p-phenylene diisocyanate (PDI), diphenylethane 4,4′-diisocyanate (EDI), diphenylmethane diisocyanate, dimethyl diphenyl 3,3′-diisocyanate, diphenylethane 1,2-diisocyanate and/or diphenylmethane diisocyanates (MDI), and prepolymers thereof.

4. The polyurethane adhesive according to claim 1, wherein the di- or polyisocyanates (A) is present in an amount of from 25 to 70 wt % based on the total weight of the polyurethane adhesive.

5. The polyurethane adhesive according to claim 1, wherein the polyol (B) is selected from the group consisting of polyetherols and polyesterols having from 2 to 8 hydrogen atoms reactive toward isocyanate.

6. The polyurethane adhesive according to claim 1, wherein the polyol (B) is present in an amount of from 15 to 45 wt % based on the total weight of the polyurethane adhesive.

7. The polyurethane adhesive according to claim 1, wherein the thermally expandable microspheres (D) has a core-shell structure, and the shell is formed of cross-linked polymer and the core is composed of physical blowing agent.

8. The polyurethane adhesive according to claim 1, wherein the thermally expandable microspheres (D) are present in an amount of from 2 to 20 wt % based on the total weight of the polyurethane adhesive.

9. The polyurethane adhesive according to claim 1, wherein the thermally expandable microspheres (D) have a starting temperature Tₛₜₐᵣₜ of 75 to 97° C.

10. The polyurethane adhesive according to claim 1, wherein the additives (E) include surfactants, foam stabilizers, pore regulators, fillers, pigments, dyes, flame retardants, antihydrolytic agents, antistatic agents, water absorbents, and agents with fungistatic and bacteriostatic action.

11. The polyurethane adhesive according to claim 1, wherein the de-bonding time of the polyurethane adhesive in hot water under temperature of 75° C. or above is less than 10 minutes.

12. The polyurethane adhesive according to claim 1, wherein the polyurethane adhesive is obtainable or obtained by the reaction of the following components:
(A) 25-70 wt % of at least one polyisocyanate;
(B) 15-45 wt % of at least one polyol;
(C) 0.01-2 wt % of catalyst
(D) 2-20 wt % of thermally expandable microspheres; and
(E) other additives, based on the total weight of the polyurethane adhesive,
wherein the isocyanate index of the reaction is in the range of from 30 to 60.

13. A process for preparing the de-bondable polyurethane adhesive according to claim 1, comprising the step of mixing the following components:
(A) at least one di- or polyisocyanate;
(B) at least one polyol;
(C) catalyst
(D) thermally expandable microspheres; and
(E) other additives,
wherein the isocyanate index is set to be in the range of from 28 to 65.

14. The process according to claim 13, wherein component (A) is added separately as component (ii) and components (B)-(E) are added together as component (i).

15. The process according to claim 14, wherein the mixing ratio of component (i) to (ii) is in the range of from 3:1 to 1:3.

16. A method of using the de-bondable polyurethane adhesives based on thermally expandable microspheres of claim 1, the method comprising using the de-bondable polyurethane based on thermally expandable microspheres for de-bonding metal and cutting pad during wafer cutting.

17. The method according to claim 16, wherein the de-bonding takes place in hot water under temperature of 75° C. or above, or 80° C. or above, or 90° C. or above, or 97° C. or above.

18. A method of using the de-bondable polyurethane adhesives based on thermally expandable microspheres of claim 1, the method comprising using the de-bondable polyurethane based on thermally expandable microspheres in mechanical property testing sample preparation.

19. The polyurethane adhesive according to claim 1, wherein the isocyanate index of the reaction is set in the range of from 30 to 50.

20. The polyurethane adhesive according to claim 1, wherein the isocyanate index of the reaction is set in the range of from 35 to 50.
